(19) United States
(12) Patent Application Publication
(10) Pub. No.: US 2012/0018901 A1
(43) Pub. Date: Jan. 26, 2012

(54) FLIP-CHIP PACKAGE AND METHOD OF MANUFACTURING THE SAME USING ABLATION

(75) Inventors: Patrick Variot, Los Gatos, CA (US); Qwai Low, Cuppertino, CA (US); Zafer Kutlu, Menlo Park, CA (US)

(73) Assignee: LSI Corporation, Allentown, PA (US)

(21) Appl. No.: 12/840,937

(22) Filed: Jul. 21, 2010

(51) Int. Cl. H01L 23/48; H01L 21/60

(52) U.S. Cl. 257/778; 438/108; 257/E21.511; 257/E23.01

(57) ABSTRACT

A method of manufacturing a flip-chip package and a flip-chip package manufactured by such method. In one embodiment, the method includes: (1) mounting a die to a first die, (2) encapsulating the second die with a molding compound and (3) selectively ablating the molding compound based on an expected heat generation of portions of the second die to reduce a thickness of the molding compound proximate the portions.

### TECHNICAL FIELD

This application is directed, in general, to flip-chip packages and, more specifically, to a mounted electronic package and method of manufacturing the same using ablation.

### BACKGROUND

With integrated circuits (ICs) generating more and more power, heat dissipation for packaged devices becomes a more substantial issue. In so-called “flip-chip” packages, the best thermal path from a packaged die is frequently by way of the back side of the upper die (the die distal to the substrate on which the flip-chip is eventually mounted. However, molded flip-chip packages overlay a molding compound on the back side of the IC, which provides a disadvantageous thermal resistance.

Decreasing this thermal resistance involves exposing the back side of the IC. The current technique involves fitting the mold cavity with a compliant material, such as rubber. The compliant material contacts the back side of the IC during molding and prevents the molding compound from covering the back side, at least in theory. The theory has not translated well to practice. In practice, the compliant material rarely forms a suitable seal with the back side and therefore permits some molding compound to coat to the back side. That molding compound amounts to flash that has to be cleaned off the back side after the molding compound has cured. Even if the compliant material does form a suitable seal with the back side, the wear that results from molding multiple ICs rapidly deforms and degrades the compliant material and compromises the seal. This requires the compliant material to be replaced often.

Adding to the above complications, mold pressures must also be tightly controlled so that a suitable seal is formed and maintained between the compliant material and the back side of the IC. Finally, the compliant material needs to be of a different size, shape or thickness if a common mold is to be used on different IC sizes, shapes or thicknesses. This further slows manufacturing rates, increases costs and threatens yield.

### SUMMARY

One aspect provides a method of manufacturing a flip-chip package. In one embodiment, the method includes: (1) mounting a second die to a first die, (2) encapsulating the second die with a molding compound and (3) selectively ablating the molding compound based on an expected heat generation of portions of the second die to reduce a thickness of the molding compound proximate the portions.

Another aspect provides a flip-chip package manufactured by a method. In one embodiment, the method includes: (1) mounting a second die to a first die, (2) encapsulating the second die with a molding compound and (3) selectively ablating the molding compound based on an expected heat generation of portions of the second die to reduce a thickness of the molding compound proximate the portions.

Yet another aspect provides a method of manufacturing a flip-chip package. In one embodiment, the method includes: (1) providing a first die, (2) mounting a second die to the first die, (3) encapsulating the second die with a molding compound, (4) curing the molding compound and (5) selectively ablating the molding compound with a laser based on an expected heat generation of portions of a back surface of the second die to reduce a thickness of the molding compound proximate the portions.

### BRIEF DESCRIPTION

Reference is now made to the following descriptions taken in conjunction with the accompanying drawings, in which:

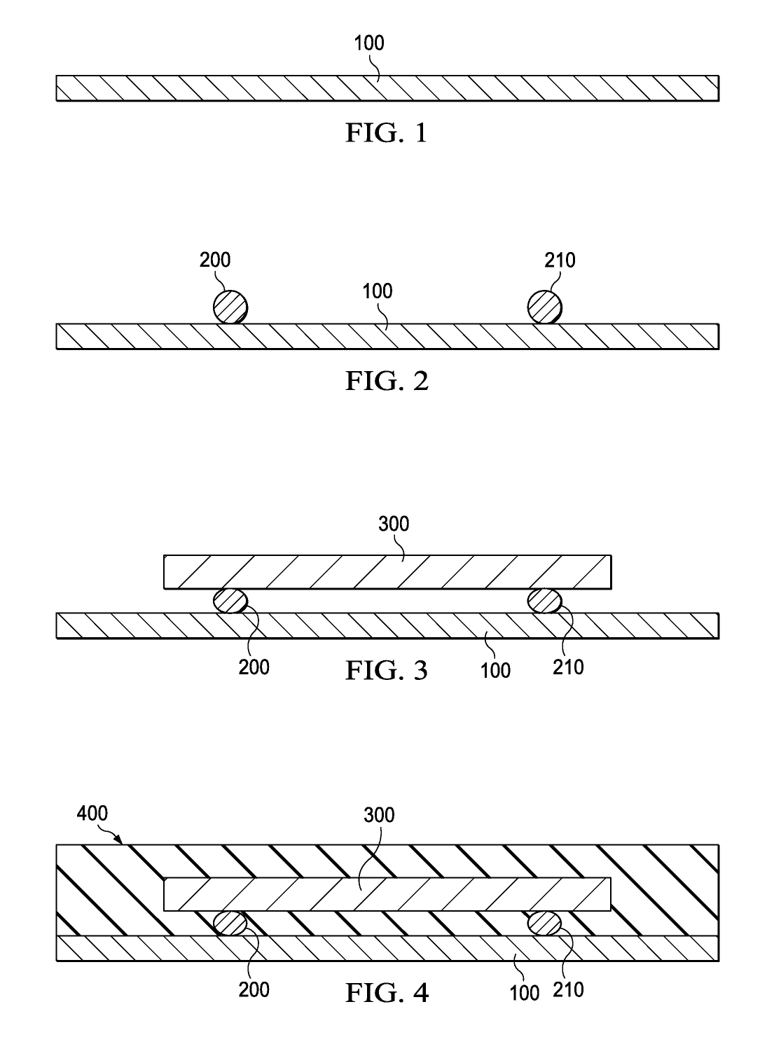

FIG. 1 is an elevational, cross-sectional view of one embodiment of a flip-chip package having an exposed surface after a first intermediate step of manufacture thereof;

FIG. 2 is an elevational, cross-sectional view of one embodiment of a flip-chip package having an exposed surface after a second intermediate step of manufacture thereof;

FIG. 3 is an elevational, cross-sectional view of one embodiment of a flip-chip package having an exposed surface after a third intermediate step of manufacture thereof;

FIG. 4 is an elevational, cross-sectional view of one embodiment of a flip-chip package having an exposed surface after a fourth intermediate step of manufacture thereof;

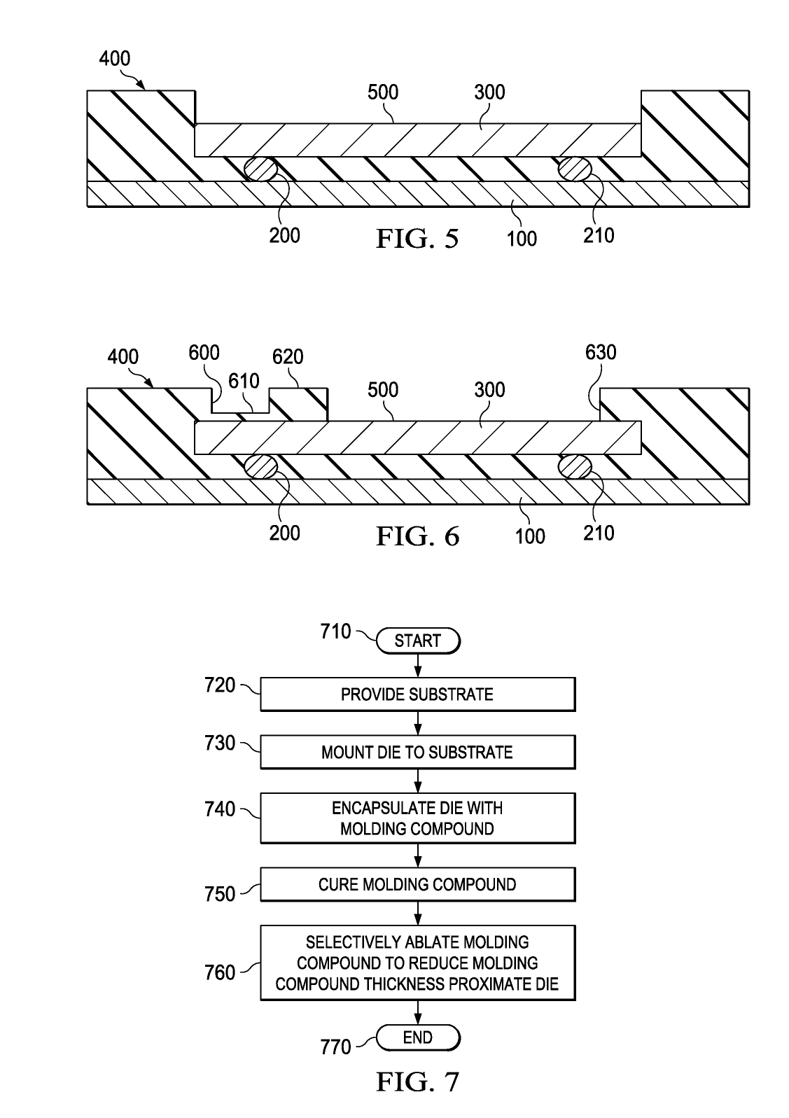

FIG. 5 is an elevational, cross-sectional view of one embodiment of a flip-chip package having an exposed surface after one embodiment of a fifth intermediate step of manufacture thereof;

FIG. 6 is an elevational, cross-sectional view of one embodiment of a flip-chip package having an exposed surface after an alternative embodiment of the fifth intermediate step of manufacture thereof; and

FIG. 7 is a flow diagram of one embodiment of a method of manufacturing a flip-chip package having an exposed surface.

### DETAILED DESCRIPTION

Introduced herein are various embodiments of a method of manufacturing a flip-chip package in which the circuit package has an exposed surface. The method employs an ablation step in which a molding compound that has been employed to encapsulate the flip-chip package is at least partially ablated to expose at least a portion of a surface of a second die in the flip-chip package. In certain embodiments, exposure of at least a portion of the surface of the second die increases the rate at which heat is dissipated from the second die or the flip-chip package as a whole. In one embodiment, a laser is employed to carry out the ablation step. In another embodiment, at least a portion of the back surface of the second die is exposed by ablation. In yet another embodiment, only a portion of the back surface is exposed by ablation; the remaining portion remains occluded by the molding compound. If the remaining portion extends to one or more edges of the second die, it serves to hold the second die in place relative to the first die. In yet another embodiment, the second die is an IC.

FIG. 1 is an elevational, cross-sectional view of one embodiment of a electronic die having an exposed surface after a first intermediate step of manufacture thereof. The first intermediate step is that of providing a first die 100. The term “intermediate step” denotes that one or more additional manufacturing steps, trivial or substantial, may, but need not, precede or follow the intermediate step. The first die 100 may be of any conventional or later-developed type. Those skilled in the pertinent art will understand that the first die 100 may take other conventional or later-developed forms without departing from the broad scope of the invention.

In the embodiment of FIG. 1, the first die 100 is generally planar and has at least one interconnect layer (not shown) to which is coupled a plurality of exposed conductive pads (also not shown) configured to receive conductors associated with a die. In one embodiment, the conductive pads are configured to receive and adhere to solder to form a ball-grid array (BGA) to mount a die to the first die 100. In one alternative embodiment, the conductive pads are configured to receive and adhere to solder to surface-mount leads of a second die (not shown). In another alternative embodiment, the conductive pads associated holes and are configured to receive through-hole leads of a second die (not shown). Those skilled in the pertinent art will understand that other conventional and later-developed mounting configurations are possible and fall within the broad scope of the invention.

FIG. 2 is an elevational, cross-sectional view of one embodiment of a flip-chip package having an exposed surface after a second intermediate step of manufacture thereof. The second intermediate step is that of placing one or more solder balls 200, 210 on the first die 100. In one embodiment, the one or more solder balls 200, 210 are formed onto the first die 100 using a conventional solder paste/reflow technique. In another embodiment, the one or more solder balls 200, 210 are formed onto the first die 100 using a conventional solder electroplate/reflow technique. Those skilled in the pertinent art understand how to place one or more solder balls 200, 210 on a first die such that the solder balls 200, 210 can later cooperate to form a BGA mounting for a die on the first die 100. Alternative embodiments may employ solder in various amounts or configurations to create a surface or through-hole mount for the die on the first die 100.

FIG. 3 is an elevational, cross-sectional view of one embodiment of a flip-chip package having an exposed surface after a third intermediate step of manufacture thereof. The third intermediate step is that of mounting a second die 300 on the first die 100 using the solder balls 200, 210. More specifically, after the solder balls 200, 210 are placed on the first die 100, the second die 300 is placed over the solder balls 200, 210. The solder balls 200, 210 are then heated until they “reflow.” The solder balls 200, 210 are then allowed to cool, affixing the second die 300 to the first die 100.

FIG. 4 is an elevational, cross-sectional view of one embodiment of a flip-chip package having an exposed surface after a fourth intermediate step of manufacture thereof. The fourth intermediate step is that of encapsulating (sometimes called “potting”) the second die 300 with a molding compound 400. FIG. 4 shows the molding compound 400 surrounding the second die 300 and covering the first die 100. The molding compound 400 may also surround the solder balls 200, 210 and the first die 100.

Those skilled in the pertinent art are familiar with the types and uses of conventional molding compounds and conventional techniques for molding flip-chips. Those skilled in the pertinent art should also understand that the broad scope of the invention encompasses both conventional and later-developed molding compounds and techniques for molding flip-chips.

FIG. 5 is an elevational, cross-sectional view of one embodiment of a flip-chip package having an exposed surface after one embodiment of a fifth intermediate step of manufacture thereof. The fifth intermediate step is that of selectively ablating the molding compound 400 such that the thickness of the molding compound 400 proximate the second die 300 is reduced. In a more specific embodiment, the molding compound 400 is ablated such that it is substantially removed from at least a portion of an upper surface 500 of the second die 300. In the illustrated embodiment, the molding compound 400 is ablated such that it is substantially removed from substantially all of the upper surface 500.

FIG. 6 is an elevational, cross-sectional view of one embodiment of a flip-chip package having an exposed surface after an alternative embodiment of the fifth intermediate step of manufacture thereof. In the alternative embodiment of FIG. 6, the molding compound 400 is selectively removed such that only part of the upper surface 500 of the second die 300 is exposed. As FIG. 6 shows, some molding compound 400 is allowed to remain on the surface 500. Specifically, a portion 600 of the remaining molding compound 400 extends to an edge of the second die 300 and therefore serves to hold the second die 300 in place relative to the first die 100. Thus the remaining molding compound 400 continues to occlude a peripheral portion of the surface 500. Another portion 610 of the remaining molding compound 400 is reduced in thickness but not substantially removed. Yet another portion 620 of the remaining molding compound 400 is substantially unablated. Still another portion 630 of the molding compound 400 extends to another edge of the second die 300 (serving to hold the second die 300 in place relative to the first die 100) but extends from the other edge to a degree differing from that of the portion 600.

Ablation, and more specifically, laser ablation, is a relatively benign process that is capable of removing molding compound without placing significant mechanical stress on the second die 300. Those skilled in the pertinent art understand that avoiding significant mechanical stress is advantageous.

In various embodiments, the molding compound is removed based on the expected heat generation of the second die 300. In a more specific embodiment, the molding compound is removed as a function of the expected heat generation. In one embodiment, the molding compound proximate portions of the second die 300 that are expected to generate more heat (typically those having high concentrations of active circuitry) is ablated more than the molding compound proximate portions of the second die 300 that are expected to generate less heat. In a more specific embodiment, the portions of the surface of the second die 300 that are expected to generate more heat are exposed, while the remaining portions are unablated.

Those skilled in the pertinent art are familiar with various ablation techniques, including laser ablation. For this reason, a general discussion of ablation and laser ablation are outside the scope of this Detailed Description. However, Phipps, “Laser Ablation and Its Applications,” Vol. 129 of the Springer Series in Optical Sciences, 2007, addresses laser ablation in depth and is incorporated herein by reference as one example of a general reference on laser ablation.

Having described various embodiments of a flip-chip package before and after several intermediate manufacturing steps thereof, various embodiments of a method of manufacturing a flip-chip package will now be described. Accordingly, FIG. 7 is a flow diagram of one embodiment of a method of manufacturing a flip-chip package having an exposed surface. The method begins in a start step 710. In a step 720, a first die is provided. As described above, the first die may be of any type whatsoever. While the first die may perform other functions, it need only provide a surface on which to mount a die. In a step 730, a second die is mounted to the first die. As described above, the second die may be mounted to the first die using any conventional or later-developed mounting technique. The mounting may be only mechanical (e.g., nonconductive adhesive or nonconductive interlocking structure) or both electrical and mechanical (e.g., solder or conductive interlocking structure). In a step 740, the second die is encapsulated with a molding compound. As described above, the molding compound may be of any conventional or later-developed type. In a step 750, the molding compound is cured. In an alternative embodiment, the molding compound does not need to cure. In a step 760, the molding compound is selectively ablated to reduce its thickness proximate the second die. In one embodiment, the thickness is reduced to zero. In another embodiment, a laser is employed to carry out the selective ablation. In yet another embodiment, the molding compound is ablated to expose a surface of the second die. In still another embodiment, only a portion of the surface of the second die is exposed; the molding compound continues to occlude another portion of the surface. In one more specific embodiment, the exposed portions of the surface are those responsible for higher heat generation. In another more specific embodiment, the occluded portion of the surface is proximate the periphery of the second die such that the molding compound forms a retentive lip around the second die. In one embodiment, ablation occurs before or during the curing of the molding compound, if the molding compound needs to cure. The method ends in an end step 770.

Those skilled in the art to which this application relates will appreciate that other and further additions, deletions, substitutions and modifications may be made to the described embodiments.

What is claimed is:

1. A method of manufacturing a flip-chip package, comprising:
mounting a second die to a first die;
encapsulating said second die with a molding compound; and
selectively ablating said molding compound based on an expected heat generation of portions of said second die to reduce a thickness of said molding compound proximate said portions.

2. The method as recited in claim 1 wherein said selectively ablating is carried out with a laser.

3. The method as recited in claim 1 wherein said selectively ablating comprises exposing at least a portion of a surface of said second die.

4. The method as recited in claim 3 wherein said surface is a back surface.

5. The method as recited in claim 1 wherein said molding compound continues to occlude a peripheral portion of said surface after said selectively ablating.

6. The method as recited in claim 1 further comprising curing said molding compound before said selectively ablating.

7. The method as recited in claim 1 wherein said flip-chip package is a flip-chip package.

8. The method as recited in claim 1 wherein said second die is an integrated circuit (IC).

9. A flip-chip package manufactured by a method comprising:
mounting a second die to a first die;
encapsulating said second die with a molding compound; and
selectively ablating said molding compound based on an expected heat generation of portions of said second die to reduce a thickness of said molding compound proximate said portions.

10. The flip-chip package as recited in claim 9 wherein said selectively ablating is carried out with a laser.

11. The flip-chip package as recited in claim 9 wherein said selectively ablating comprises exposing at least a portion of a surface of said second die.

12. The flip-chip package as recited in claim 12 wherein said surface is a back surface.

13. The flip-chip package as recited in claim 9 wherein said molding compound continues to occlude a peripheral portion of said surface after said selectively ablating.

14. The flip-chip package as recited in claim 9 wherein said process further comprises curing said molding compound before said selectively ablating.

15. The flip-chip package as recited in claim 9 wherein said flip-chip package is a flip-chip package.

16. The flip-chip package as recited in claim 9 wherein said second die is an integrated circuit (IC).

17. A method of manufacturing a flip-chip package, comprising:
providing a first die;
mounting a second die to said first die;
encapsulating said second die with a molding compound;
curing said molding compound; and
selectively ablating said molding compound with a laser based on an expected heat generation of portions of a back surface of said second die to reduce a thickness of said molding compound proximate said portions.

18. The method as recited in claim 17 wherein said flip-chip package is a flip-chip package.

19. The method as recited in claim 17 wherein said second die is an integrated circuit (IC).

20. The method as recited in claim 17 wherein said selectively ablating comprises selectively ablating said molding compound as a function of said expected heat generation.
